(19) United States
(12) Patent Application Publication
(10) Pub. No.: US 2009/0087932 A1
(43) Pub. Date: Apr. 2, 2009

(54) SUBSTRATE SUPPORTING APPARATUS, SUBSTRATE SUPPORTING METHOD, SEMICONDUCTOR MANUFACTURING APPARATUS AND STORAGE MEDIUM

(75) Inventor: Keisuke Kondoh, Yamanashi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/209,687

(22) Filed: Sep. 12, 2008

(30) Foreign Application Priority Data
Sep. 28, 2007 (JP) 2007-255681

(51) Int. Cl. H01L 21/00; H01L 21/306; H01L 21/30

(52) U.S. Cl. 438/30; 156/345.27; 118/666; 438/706; 118/733; 257/E21.215; 257/E21.001

(57) ABSTRACT

A substrate supporting apparatus includes a substrate supporting portion having a substrate supporting surface facing a rear surface of a substrate; plural protruding portions provided on the substrate supporting surface, for preventing the substrate from being slid on the substrate supporting surface by friction force generated in relation with the substrate; a gas discharge opening provided in the substrate supporting surface, for discharging gas toward the rear surface of the substrate; a gas flow path whose one end is connected to the gas discharge opening; and a temperature control unit for controlling temperature of the gas flowing through the gas flow path, wherein the gas discharged to the rear surface of the substrate flows in a gap between the substrate supporting surface and the substrate, and by Bernoulli effect causing reduction of pressure of the gap, the substrate is attracted to the substrate supporting portion, thereby supporting the substrate.

### FIELD OF THE INVENTION

The present disclosure relates to a substrate supporting apparatus for supporting a substrate under an atmospheric atmosphere; a substrate supporting method; a semiconductor manufacturing apparatus using the substrate supporting apparatus; and a storage medium storing therein a program for controlling an operation of the substrate supporting apparatus.

### BACKGROUND OF THE INVENTION

In a manufacturing process of a semiconductor device or a flat panel such as a liquid crystal display or the like, a substrate called a semiconductor wafer (hereinafter, referred to as “wafer”) or a glass substrate is accommodated in a carrier and is loaded into a loading port of a semiconductor manufacturing apparatus (including a flat panel manufacturing apparatus). Then, the substrate is taken out from the carrier by a transfer arm in the apparatus and is transferred into a processing module.

One example of such semiconductor manufacturing apparatus is a so-called multi-chamber system including a first transfer chamber connected to a loading port and maintained under an atmospheric atmosphere; a second transfer chamber connected to a plurality of processing modules for performing an etching process or a film forming process by a CVD (Chemical Vapor Deposition) and maintained under a vacuum atmosphere which is common to the processing modules; and a load lock chamber disposed between the first and second transfer chambers, for accommodating a wafer in a standby state, wherein the inside of the load lock chamber can be switched between the atmospheric atmosphere and the vacuum atmosphere. Each of the first and second transfer chambers includes a multi-joint transfer arm having, at its leading end portion, a wafer supporting portion (pick) for supporting a rear surface of the wafer. Further, connected to the first transfer chamber is an alignment chamber including an orienter for performing a position alignment of the wafer. The orienter carries out the position alignment of the wafer by rotating the wafer around a vertical axis via a pedestal (stage) supporting a center of the rear surface of the wafer to thereby orient a notch formed at a peripheral portion of the wafer toward a certain direction.

After the wafer is unloaded from the carrier, the position of the wafer is adjusted by the orienter, and then the wafer is transferred by each transfer arm into a processing module to be processed therein. Then, the wafer is kept in the load lock chamber until it is cooled, and returned to the carrier thereafter. Here, the reason for returning the wafer to the carrier after the wafer is sufficiently cooled is that, if a high-temperature wafer is loaded into the carrier, there is a likelihood that particles would be generated from the composition constituting the carrier and dispersed, thereby adhering to the wafer.

However, it is very unlikely that the particles are adhered to the wafer heated up to a certain temperature. Further, it is required to heat up the wafer before its transfer to the processing module for performing the CVD in order to remove organic matters adhered thereto, to thereby prevent an entrance of foreign substances into a film to be formed. Moreover, it is also required to improve throughput by shortening the cooling time in the load lock chamber before the wafer is returned to the carrier. In consideration of all these requirements, it has been under investigation to provide the transfer arms and the orienter with a temperature control function implemented by a wafer heating unit and a wafer cooling unit so as to perform a temperature control while the wafer is being transferred or the position alignment of the substrate is being performed.

As another example of the semiconductor manufacturing apparatus besides the multi-chamber system, there is a coating and developing apparatus used in a photoresist process, which is one of semiconductor manufacturing processes. The coating and developing apparatus is generally connected to an exposure apparatus. After a resist is coated on a wafer, the wafer is loaded into the exposure apparatus, and after the completion of an exposure process, the wafer is returned back into the coating and developing apparatus to be subjected to a developing process therein. Until the wafer is loaded into the exposure apparatus after the coating of the resist, the wafer needs to be maintained at a specific temperature, for example, about 23° C., depending on the temperature inside the exposure apparatus. Further, it is also necessary to perform the position alignment of the wafer by the orienter before the wafer is subjected to the exposure process after the resist coating. Accordingly, by installing the orienter having the aforementioned temperature control function in the coating and developing apparatus, the position alignment and the temperature control of the wafer can be carried out at the same time, so that throughput can be improved.

The heating unit performing the temperature control function may be implemented by, for example, attaching a sheet-shaped heating wire heater to a wafer contact portion of the wafer supporting portion of the transfer arm and a wafer contact portion of the pedestal of the orienter, respectively. Further, the cooling unit conducting the temperature control function may be implemented by forming a coolant pathway for a liquid coolant at the wafer contact portion and flowing the coolant through the coolant pathway.

However, the wafer supporting portion of the transfer arm is configured to have a large rotation angle to transfer the wafer to each processing chamber of the semiconductor manufacturing apparatus. Further, the rotation angle of the pedestal of the orienter is also set to be large because the orienter needs to be rotated by at least 360 degrees to detect the notch of the wafer. If the heater is installed in and a wire is connected to the component having such large rotation angles, it is likely that the wire is drawn to the floor and worn away and finally be cut due to the rotation. Furthermore, if the heater is installed in the wafer supporting portion of the transfer arm, the weight thereof increases, resulting in an increase of a load exerted on each component of the transfer arm. In such case, the components are more likely to be worn away. Besides, since the thickness of the wafer supporting portion increases, design of each processing module, i.e., the transfer destination point, may need to be modified, which is regarded impractical.

Furthermore, when the coolant pathway is formed in the wafer supporting portion or the pedestal, measures to prevent coolant leakage are required, which is regarded impractical, too. Further, the formation of the coolant pathway in the wafer supporting portion also causes increases in the thickness and the weight of the wafer supporting portion as in the case of installing the heater. Though Patent Document 1 discloses a multi-joint transfer arm, it does not mention any of the aforementioned problems. [Patent Document 1] Japanese Patent Laid-open Publication No. 2000-72248

### BRIEF SUMMARY OF THE INVENTION

In view of the foregoing, the present disclosure provides a substrate supporting apparatus capable of performing a temperature control of a substrate while the substrate is being transferred in an atmospheric atmosphere or a position alignment of the substrate is being performed, and also provides a semiconductor manufacturing apparatus including the substrate supporting apparatus, a substrate supporting method, and a storage medium storing therein a program for executing the method.

In accordance with an aspect of the present invention, there is provided a substrate supporting apparatus including: a substrate supporting portion having a substrate supporting surface facing a rear surface of a substrate; a plurality of protruding portions provided on the substrate supporting surface, for supporting the rear surface of the substrate and preventing the substrate from being slid on the substrate supporting surface by a friction force generated between the protruding portions and the substrate; a gas discharge opening provided in the substrate supporting surface, for discharging a gas toward the rear surface of the substrate; a gas flow path whose one end is connected to the gas discharge opening and the other end is connected to a gas supply source for supplying the gas to the gas discharge opening; and a temperature control unit for controlling a temperature of the gas flowing through the gas flow path, wherein the gas discharged to the rear surface of the substrate flows in a gap between the substrate supporting surface and the substrate, and by a Bernoulli effect causing a reduction of a pressure of the gap, the substrate is attracted to the substrate supporting portion, thereby supporting the substrate.

The substrate supporting apparatus may further include a driving mechanism for allowing the substrate supporting portion to rotate about a vertical axis and to move forward and backward. In this case, it is possible that the driving mechanism constitutes a multi-joint arm together with the substrate supporting portion. Further, it is also possible that the gas flow path is formed inside the driving mechanism. Furthermore, it is also possible that the substrate is a semiconductor wafer, and the substrate supporting portion is configured as a rotary stage for detecting a direction of the semiconductor wafer and adjusting the direction to be coincident with a preset direction.

In accordance with another aspect of the present invention, there is provided a substrate supporting method including: discharging a gas from a gas discharge opening provided in a substrate supporting surface toward a rear surface of a substrate placed on a plurality of protruding portions, in which the protruding portions are installed on the substrate supporting surface provided on a substrate supporting portion while facing the rear surface of the substrate, for supporting the rear surface of the substrate and preventing the substrate from being slid on the substrate supporting surface by a friction force generated between the protruding portions and the substrate; controlling, by a temperature control unit, a temperature of the gas flowing through a gas flow path whose one end is connected to the gas discharge opening and the other end is connected to a gas supply source; and supporting the substrate by the substrate supporting portion through attracting the substrate to the substrate supporting portion as a result of a Bernoulli effect which causes a reduction of a pressure of a gap between the substrate supporting surface and the substrate when the gas discharged to the rear surface of the substrate flows in the gap.

In accordance with still another aspect of the present invention, there is provided a semiconductor manufacturing apparatus including: a first transfer chamber under an atmospheric atmosphere, including a mounting unit for mounting thereon a carrier for accommodating a substrate therein; a load lock chamber including a mounting table for mounting thereon the substrate, for switching between an atmospheric atmosphere and a vacuum atmosphere; a vacuum processing module connected to the first transfer chamber via the load lock chamber, for performing a process on the substrate under a vacuum atmosphere; a first substrate transfer member for transferring the substrate between the carrier disposed in the first transfer chamber and the load lock chamber; and a second substrate transfer member for transferring the substrate between the load lock chamber and the vacuum processing module, wherein the first substrate transfer member is configured as the substrate supporting apparatus in accordance with the above described present invention. It is possible that an alignment chamber having a substrate position adjusting member for adjusting a position of the substrate is connected to the first transfer chamber, and the substrate position adjusting member is configured as the substrate supporting apparatus.

In accordance with still another aspect of the present invention, there is provided a storage medium for storing a program used in a substrate supporting apparatus, wherein the program includes steps for executing the above described substrate supporting method.

The substrate supporting apparatus in accordance with the present disclosure includes the substrate supporting portion which discharges the gas from the gas discharge opening to the rear surface of the substrate supported on the protruding portions such that the substrate is attracted and held thereon by the Bernoulli effect; and the temperature control unit for controlling the temperature of the gas flowing through the gas flow path connected to the gas discharge opening to thereby adjust the temperature of the substrate while the substrate is supported. For example, by applying the present disclosure to a substrate transfer means or a substrate position adjusting means installed in the semiconductor manufacturing apparatus, the throughput can be improved in comparison with a case when the heating and the transfer of the substrate is performed individually or when the heating and the position adjustment of the substrate is performed individually. Further, by allowing the substrate to have a certain temperature during the transfer or the position adjustment of the substrate, the adhesion of the particle to the substrate can be suppressed.

### BRIEF DESCRIPTION OF THE DRAWINGS

The disclosure may best be understood by reference to the following description taken in conjunction with the following figures:

FIG. 1 provides a perspective view of a transfer device in accordance with an embodiment of the present invention;

FIG. 2 sets forth a longitudinal side view of the transfer device;

FIG. 3 presents a top view of a wafer supporting portion of the transfer device;

FIG. 4 illustrates a longitudinal side view of the wafer supporting portion;

FIG. 5 depicts a longitudinal side view of an orienter in accordance with an embodiment of the present invention;

FIG. 6 provides a transversal plane view of the orienter;

FIG. 7 shows a plane view of a semiconductor manufacturing apparatus employing the transfer device and the orienter; and

FIG. 8 offers a longitudinal side view of the semiconductor manufacturing apparatus.

### DETAILED DESCRIPTION OF THE INVENTION

Hereinafter, embodiments of the present invention will be described in detail with reference to the accompanying drawings.

### First Embodiment

As a first embodiment of the present invention, an example, in which a substrate supporting apparatus is applied to a transfer device for transferring a wafer as a substrate, will be explained.

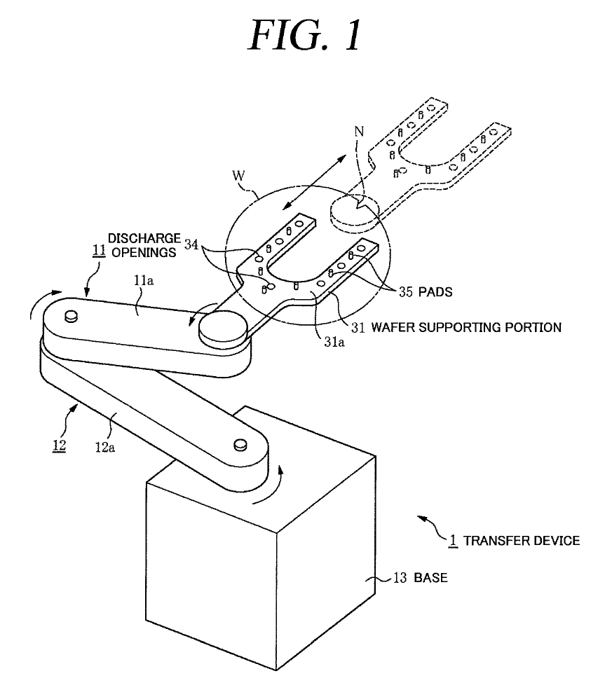

A transfer device 1 performs a transfer of a wafer W while attracting and holding the wafer W by using a Bernoulli chuck using a Bernoulli effect, and is installed in an atmospheric atmosphere to obtain the Bernoulli effect. FIG. 1 presents a perspective view of the transfer device 1, and, as shown in the figure, the transfer device 1 includes a wafer supporting portion (pick) 31 for supporting the wafer W, provided at its leading end portion; an intermediate arm portion 11; and a revolving arm portion 12. A base end side of the wafer supporting portion 31 is coupled to a leading end side of the intermediate arm portion 11 and a base end side of the intermediate arm portion 11 is coupled to a leading end side of the revolving arm portion 12, such that they can rotate around vertical axes. The transfer device 1 is configured as a well-known multi-joint (scalar) transfer arm. Further, a base end side of the revolving arm portion 12 is coupled to a base 13 such that it can rotate around the vertical axis.

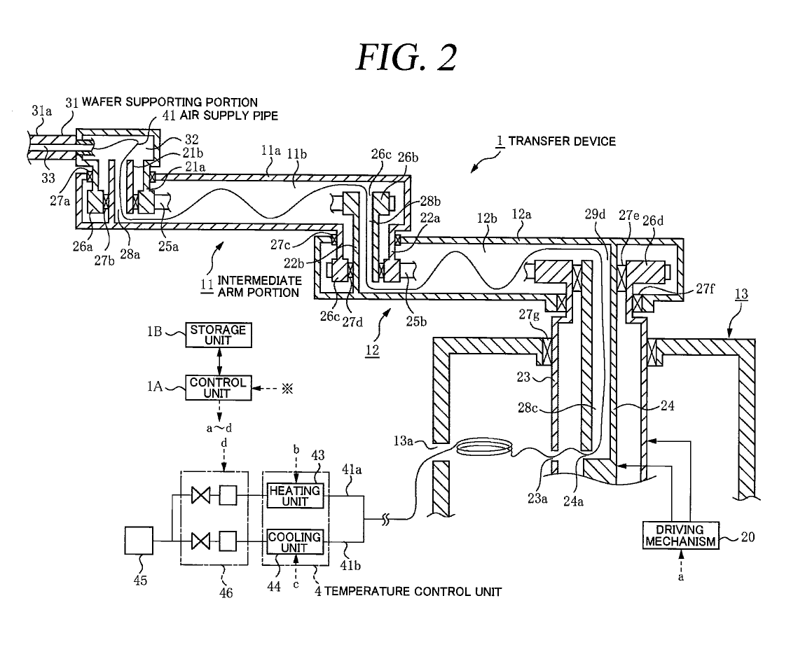

FIG. 2 provides a longitudinal side view showing the base end side of the wafer supporting portion 31, the intermediate arm portion 11, the revolving arm portion 12 and the base 13. As illustrated in this figure, the intermediate arm portion 11 and the revolving arm portion 12 have main bodies formed of aluminum casings 11a and 12a, respectively. Accommodated in a space 11b inside the casing 11a are a rotational shaft 21a and a supporting shaft 21b which connect the wafer supporting portion 31 with the intermediate arm portion 11, and accommodated in a space 12b inside the casing 12a are a rotational shaft 22a and a supporting shaft 22b which connect the intermediate arm portion 11 with the revolving arm portion 12.

Further, a rotational shaft 23 and a revolving shaft 24 installed at the base end side of the revolving arm portion 12 are connected to a driving mechanism 20 made up of, for example, a motor, which serves to rotate the shafts 23 and 24 independently around a vertical axis. Further, reference numerals 25a and 25b are timing belts, and reference numerals 26a to 26d are pulleys, wherein the timing belts 25a and 25b and the pulleys 26a to 26d serve to deliver a driving force from the driving mechanism 20, and shaft receiving portions 27a to 27g configured as, for example, bearings are interposed between the rotatably interconnected members.

In the above-described configuration, if the rotational shaft 23 is driven while the revolving shaft 24 is stopped, the revolving arm portion 12 and the wafer supporting portion 31 are rotated in the same direction, while the intermediate arm portion 11 is rotated in the reverse direction to offset the rotations of the revolving arm portion 12 and the wafer supporting portion 31. As a result of the combination of these movements, the transfer device 1 makes an extending/contracting motion for moving the wafer supporting portion 31 in a forward/backward direction, as illustrated by a broken line in FIG. 1. On the other hand, if the rotational shaft 23 and the revolving shaft 24 are rotated in the same direction, the transfer device 1 makes a rotating motion in the horizontal direction of the revolving arm portion 12 without making the extending/contracting motion. When the transfer device 1 makes the extending/contracting motion, a stop position of the wafer supporting portion 31 is controlled by a driving amount of the driving mechanism 20 (for example, a rotation amount of the motor) during a time period from an initiation of the extending operation of the transfer device 1 till its stop. The operation of the driving mechanism 20 is controlled by a control unit 1A to be described later.

Provided inside the supporting shaft 21b on the leading end side of the intermediate arm portion 11, the supporting shaft 22b on the leading end side of the revolving arm portion 12, and the revolving shaft 24 are pipelines 28a to 28c, respectively, which are configured as cavity portions formed in the respective axial directions. In FIG. 2, reference numerals 23a, 24a and 13a denote through holes provided in the rotational shaft 23, the revolving shaft 24 and the base 13, respectively. Further, the pulley 26b is provided with a hole 26c communicating with the pipeline 28b and the space 11b.

One end of an air supply pipe 41 is connected to the base end side of the wafer supporting portion 31, and the other end of the air supply pipe 41 is drawn from a space 32 provided on the base end side of the wafer supporting portion 31 into the space 11b through the pipeline 28a, and then is arranged into the space 12b through the hole 26c and the pipeline 28b in sequence to be led into the pipeline 28c. Then, the other end of the air supply pipe 41 drawn into the pipeline 28c is taken outside the rotational shaft 23 through the through holes 24a and 23a in sequence and finally taken outside the base 13 through the through hole 13a by being bifurcated into air supply pipes 41a and 41b. End portions of the air supply pipes 41a and 41b are coupled to an air supply source 45, which stores dry air therein, via a heating unit 43 and a cooling unit 44, respectively.

Further, on the air supply pipes 41a and 41b, a flow rate controller 46 including a valve, a mass flow controller, or the like is interposed between the air supply source 45 and the heating unit 43 and between the air supply source 45 and the cooling unit 44.

The heating unit 43 and the cooling unit 44 constitute a temperature control unit 4. The heating unit 43 is made by installing a heater in an air flow path, and by controlling power supplied to the heater by the control unit 1A, the temperature of air passing through the air supply pipe 41a is controlled. The cooling unit 44 is configured as a secondary flow path of a heat exchanger, and the amount of heat exchanged between the cooling unit 44 and a coolant flowing through a primary flow path of the heat exchanger is controlled by way of, for example, controlling the flow rate of the coolant by the control unit 1A, whereby the temperature of a gas in the air supply pipe 41b is controlled. Further, the control unit 1A controls the flow rates of the air each passing through the air supply pipes 41a and 41b via the flow rate controller 46.

Inside the transfer device 1, the air supply pipe 41 is made of an elastic member such as rubber or the like lest it should be cut as a result of being stretched by the rotation of the rotational shafts 21a, 22a and 23 or the revolving shaft 24. Further, the air supply pipe 41 is arranged in a winding form or in a loose form.

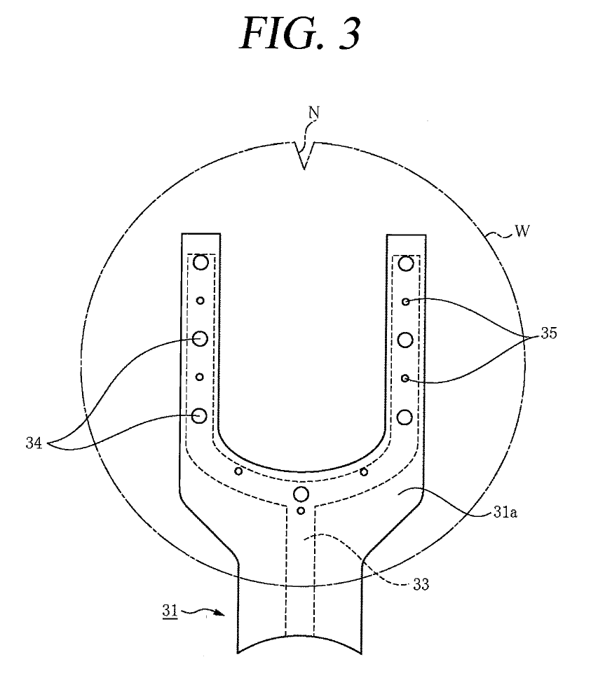

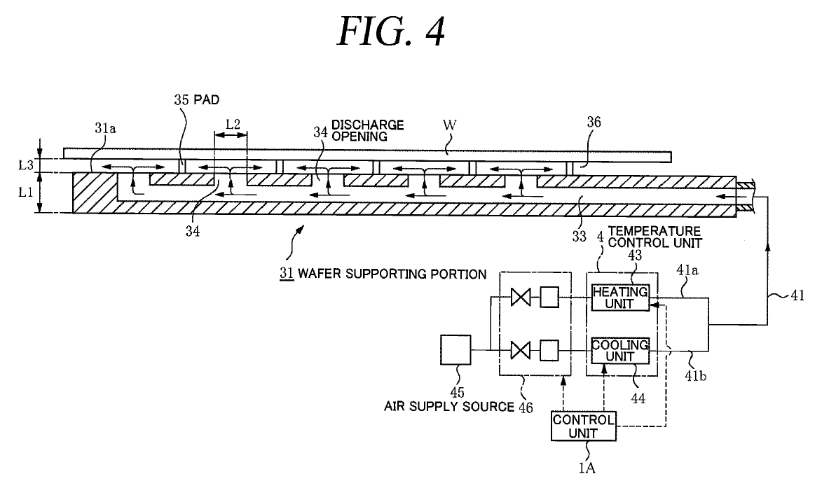

Now, the wafer supporting portion 31 will be explained with reference to FIGS. 3 and 4. FIGS. 3 and 4 provide a top view and a longitudinal side view of the wafer supporting portion 31, respectively. The wafer supporting portion 31 has, for example, a fork shape whose leading end portion is bifurcated and is made of, for example, ceramics or aluminum. As will be described later, the wafer supporting portion 31 is configured as a Bernoulli chuck, and its thickness L1 shown in FIG. 4 is set to be, for example, about 2 mm to 4 mm. Formed inside the wafer supporting portion 31 is an air flow path 33 which is extended from the base end side of the wafer supporting portion 31 toward the leading end side thereof, and a plurality of air discharge openings 34 communicating with the flow path 33 is provided in a top surface 31a of the wafer supporting portion 31. The base end side of the flow path 33 is coupled to the air supply pipe 41, so that the air heated by the heating unit 43 or the air cooled by the cooling unit 44 is discharged through the discharge openings 34. As illustrated in FIG. 4, the diameter L2 of each discharge opening 34 ranges from about 5 mm to 20 mm.

A multiplicity of rod-shaped pads 35, which are protruding portions, is provided on the top surface of the wafer supporting portion 31, and, as will be described later, a rear surface of the wafer W is pressed onto the pads 35. To prevent the wafer W from being slid on the pads 35 and fallen off when the wafer supporting portion 31 is moved forward or backward or rotated around the vertical axis, the pads 35 are made of a material having a high friction against the rear surface of the wafer W. When the rear surface of the wafer W is made of silicon, the pads 35 are desirably formed of, for example, rubber, resin, ceramics, or the like. The height L3 of each pad 35 shown in FIG. 4 ranges from about 0.5 mm to 2 mm.

The control unit 1A made up of, for example, a computer is installed in the transfer device 1. The control unit 1A includes a data processing unit having a program, a memory, and a CPU. The program enables sending a signal to each component of the transfer device 1 from the control unit 1A; performing steps to be described later to thereby carry out the transfer of the wafer W; and controlling the temperature of the wafer W. Further, for example, the memory includes a region in which processing parameters such as a processing pressure, a processing time, a gas flow rate, a power value and so forth are stored. Furthermore, when the CPU executes each command of the program, the processing parameters are read, and control signals according to the parameter values are sent to the respective components of the transfer device 1. The program (including a program related to an input manipulation or a display of the processing parameters) is installed in the control unit 1A by being stored in a storage unit 1B made up of a computer-readable storage medium such as a flexible disk, a compact disk, an MO (Magneto-Optical) disk, or the like.

Now, an operation of the above-described embodiment of the present invention will be explained. When the transfer device 1 transfers the wafer W from a certain module (departure module) to another module (destination module), as described above, the wafer supporting portion 31 is driven to rotate about the vertical axis and move forward and backward by the driving mechanism 20 via the intermediate arm portion 11 and the revolving arm portion 12, and is introduced under the rear surface of the wafer W placed in the departure module. After the wafer W is placed on the pads 35, air whose temperature is controlled at a specific temperature value is discharged from the discharge openings 34 at a certain flow rate and is flown in a gap 36 between the rear surface of the wafer W and the top surface of the wafer supporting portion 31 in a horizontal direction, as indicated by arrows in FIG. 4. Therefore, the pressure of the gap 36 is reduced to a negative pressure level, and, because of a pressure difference between this negative pressure and the atmospheric pressure above the wafer W, a force in downward direction is applied to the wafer W. As a result, the wafer W is pressed onto the top of the pads 35 and held on the wafer supporting portion 31. While held on the wafer supporting portion 31, the wafer W is exposed to the air discharged from the discharge openings 34, whereby its temperature is controlled.

The temperature of the air is regulated by the temperature control unit 4 to reach a temperature level which is required as a temperature of the wafer W when the wafer W is transferred. For example, to meet a requirement for suppressing adhesion of particles to the wafer W before an etching or film forming process is begun, the air is heated up to a preset temperature by the heating unit 43 and discharged from the discharge openings 34. Further, while the wafer W is on the way back to a carrier after a heat treatment (including the etching or film forming process) is finished, the air is cooled down to a preset temperature by the cooling unit 44 and discharged from the discharge openings 34 to meet a requirement for shortening a cooling time of the wafer W by way of cooling the wafer W while it is being transferred. Moreover, the way to control the temperature of the air is not limited to the above-described mechanism of flowing air into either one of the heating unit 43 and the cooling unit 44. It is also possible to bifurcate the air to both of the heating unit 43 and the cooling unit 44 and then join the air flows together, and to adjust the heating temperature by the heating unit 43 and the cooling temperature by the cooling unit 44, to thereby regulate the temperature of the air supplied from the discharged opening 34 to the wafer W at a desired temperature level.

When the wafer W is transferred into the destination module, the wafer W is lifted upward by, for example, an elevation pin disposed in the destination module with a force stronger than the downward force exerted on the wafer W. As a result, the wafer W is separated from the wafer supporting portion 31 to be loaded in the destination module.

In accordance with the embodiment described above, by discharging the air from the wafer supporting surface 31a of the transfer device 1 to the rear surface of the wafer W, the wafer W is attracted and held on the wafer supporting surface 31a by the Bernoulli effect. Further, since the temperature of the air is under control, the temperature of the wafer W can be heated or cooled according to the requirement for the wafer W while it is being transferred. Accordingly, there can be obtained an effect of suppressing the particle adhesion during the transfer of the wafer W. Furthermore, since the temperature of the wafer W is efficiently controlled, an effect of enhancing a throughput can also be obtained in comparison with a case of performing the transfer of the wafer W and its temperature control, e.g., the cooling, individually.

In addition, in the above-described transfer device 1, installation of a heater, a coolant pathway for a liquid coolant, and a mechanism for preventing a coolant leakage in the wafer supporting portion 31 is not required, so that the heating and cooling of the wafer W can be realized with a simple structure.

### Second Embodiment

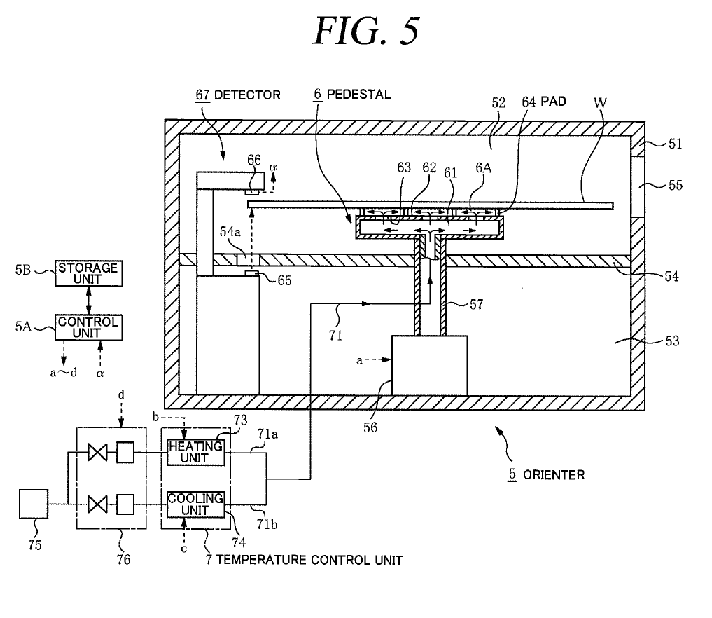

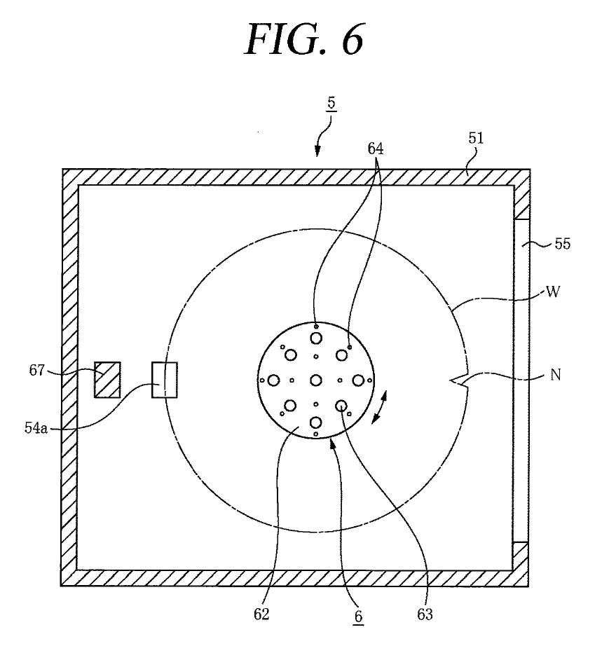

Now, as a second embodiment of the present invention, an example, in which a substrate supporting apparatus is applied to an orienter 5 serving as a position adjusting mechanism for a wafer W, will be described with reference to FIGS. 5 and 6. FIGS. 5 and 6 provide a longitudinal cross sectional view and a transversal plane view of the orienter 5, respectively. The orienter 5 includes a housing 51 and a partition plate 54 which divides the housing 51 into an upper chamber 52 and a lower chamber 53. A transfer port 55 for loading or unloading the wafer W is provided in a sidewall of the housing 51. The inside of the housing 51 is under an atmospheric atmosphere. A circular pedestal 6 configured as a Bernoulli chuck is horizontally disposed in the upper chamber 52, and the pedestal 6 is connected to a rotation driving mechanism 56 via a shaft 57 so that it can be rotated about a vertical axis, wherein the rotation driving mechanism 56 is installed in the lower chamber 53.

Formed inside the pedestal 6 is an air flow path 61 which communicates with a plurality of air discharge openings 63 provided in a top surface 62 of the pedestal 6. Further, installed on the top surface of the pedestal 6 are pads 64 which have the same configuration as that of the pads 35. If a rear surface of the central portion of the wafer W is placed on the pads 64 while air is discharged from the discharge openings 63, a force in a downward direction is exerted on the wafer W by the Bernoulli effect as in the transfer device 1, so that the wafer W is pressed onto the pads 64 and horizontally held thereon.

One end of an air supply pipe 71 is opened in the flow path 61 of the pedestal 6, and the other end of the air supply pipe 71 is taken out of the shaft 57 through, for example, a pipeline formed inside the shaft 57, and bifurcated into air supply lines 71a and 71b. An end of the air supply line 71a is coupled to an air supply source 75 via a heating unit 73 and a flow rate controller 76, while an end of the air supply line 71b is coupled to the air supply source 75 via a cooling unit 74 and the flow rate controller 76. The heating unit 73, the cooling unit 74, the air supply source 75 and the flow rate controller 76 have the same configurations as those of the heating unit 43, the cooling unit 44, the air supply source 45 and the flow rate controller 46, respectively. The heating unit 73 and the cooling unit 74 constitute a temperature control unit 7.

Further, also provided in the housing 51 is a detector 67 for detecting a position of a peripheral portion of the wafer W placed on the pedestal 6. The detector 67 includes a light emitting unit 65 disposed in the lower chamber 53 and made up of, for example, a LED; and a light receiving unit 66 disposed in the upper chamber 52 and made up of, for example, a CCD sensor. Light emitted from the light emitting unit 65 is incident upon the light receiving unit 66 through a hole 54a provided in the partition plate 54, and the light receiving unit 66 outputs a signal corresponding to the amount of the incident light to a control unit 5A.

The control unit 5A has the same configuration as that of the control unit 1A, and by executing a program stored in a storage unit 5B, the control unit 5A controls an operation of each component of the orienter 5 and also performs a position adjustment of the wafer W and a control of flow rate and temperature of the air discharged from the pedestal 6, as will be described below.

For example, if the wafer W is transferred into the housing 51 through the transport port 55 by a wafer transfer mechanism (not shown) such as the above-described transfer device 1 and the central portion of the wafer W is placed on the pedestal 6, the air discharged from the discharge openings 63 while being regulated at a preset temperature is flown in a gap 6A between the rear surface of the wafer W and the top surface 62 of the pedestal 6 in a horizontal direction, as indicated by arrows in FIG. 5. As a result, the pressure of the gap 6A is reduced to a negative pressure level, and due to a pressure difference between this negative pressure and an atmospheric pressure above the wafer W, the wafer W is pressed onto the pads 64 and held on the pedestal 6. Subsequently, the control unit 5A allows the wafer W to make approximately one rotation by means of the rotation driving mechanism 56, during which the control unit 5A detects a position of a notch N formed at the peripheral portion of the wafer W based on a variation of the amount of light incident upon the light receiving unit 66 and then operates the rotation driving mechanism 56 to orient the notch N in a certain direction. While the position adjustment of the notch N is performed, the wafer W is exposed to the air flowing under the rear surface thereof as in the case of the transfer device 1, so that the temperature of the wafer W is regulated at a certain temperature level, for example, about 30° C. to 50° C. where particle adhesion is suppressed, for example. Upon the completion of the position adjustment of the notch N, the transfer device (not shown) lifts and separates the wafer W from the pedestal 6 and transfers the wafer W out of the housing 51.

By using the orienter 5 described above, it is possible to carry out the temperature control of the wafer W while the position adjustment of the wafer W is being performed, so that the particle adhesion can be suppressed. Furthermore, as will be described below, by applying the orienter 5 to a semiconductor manufacturing apparatus, improvement of throughput can be achieved.

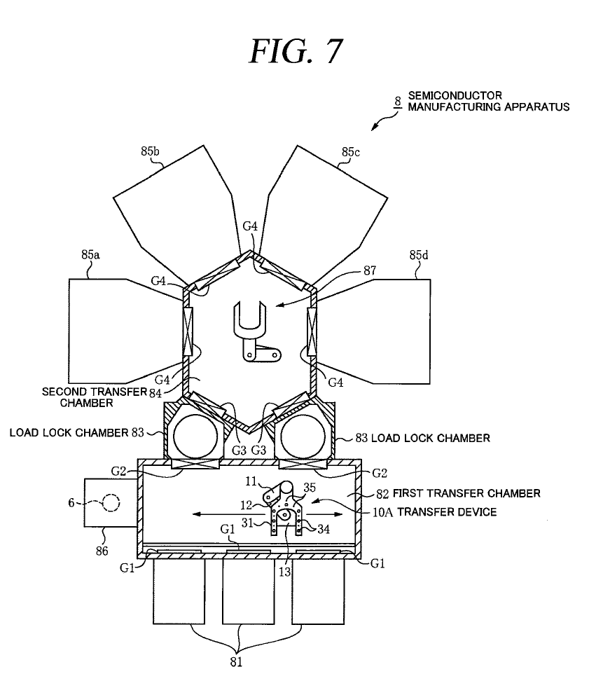

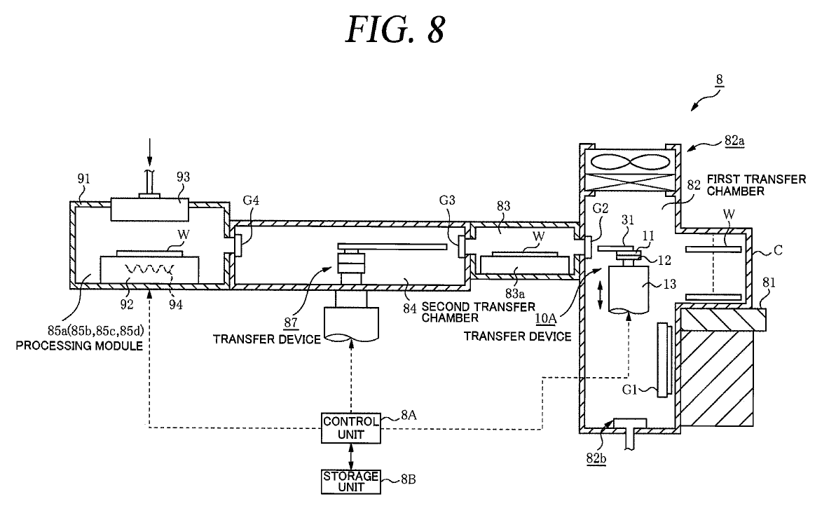

Below, an example of a semiconductor manufacturing apparatus using the transfer device 1 and the orienter 5 will be explained. FIGS. 7 and 8 present a plane view and a longitudinal side view of a semiconductor manufacturing apparatus 8 called a multi-chamber system, respectively. The semiconductor manufacturing apparatus 8 includes, for example, three carrier mounting tables 81, each mounting thereon a carrier C which accommodates therein a certain number of wafers W to be processed; a first transfer chamber 82 for transferring a wafer W under an atmospheric atmosphere; two load lock chambers 83 arranged in left and right sides, for accommodating the wafer W in a standby state, while changing their inside atmosphere between an atmospheric atmosphere and a vacuum atmosphere; a second transfer chamber 84 for transferring the wafer W under a vacuum atmosphere; and four processing modules 85a to 85d for performing certain processes on the wafer W.

These respective units of the semiconductor processing apparatus 8 are arranged in the order of the first transfer chamber 82, the load lock chambers 83, the second transfer chamber 84 and the processing modules 85a to 85d along a wafer loading direction, and neighboring units are airtightly connected to each other by doors G1 or gate valves G2 to G4. Further, the following description will be provided by defining one side of the first transfer chamber 82 as a front side.

As illustrated in FIG. 8, the carrier C mounted on the carrier mounting table 81 is connected to the first transfer chamber 82 by the door G1, and the door G1 carries out a function of opening or closing a lid of the carrier C. Further, a fan filter unit 82a including a fan for sending air into the chamber and a filter for purifying the air is disposed in a ceiling portion of the first transfer chamber 82, and an exhaust unit 82b is disposed at a bottom portion of the first transfer chamber 82 facing the fan filter unit 82a. With this configuration, a descending current of clean air is made inside the first transfer chamber 82.

A transfer device 10A corresponding to the aforementioned transfer device 1 is installed in the first transfer chamber 82. Though the transfer device 10A has the same configuration as that of the transfer device 1, a base 13 of the transfer device 10A is configured to be movable along a lengthwise direction of the first transfer chamber 82 and also movable up and down by a driving mechanism (not shown), and the transfer device 10A is adapted to transfer the wafer W between an alignment chamber 86 and the carrier C, as will be described below. Further, the alignment chamber 86 including the orienter 5 is installed at a lateral portion of the first transfer chamber 82.

Each of the two left and right load lock chambers 83 includes a mounting table 83a for mounting thereon the wafer W loaded therein, and is connected to a vacuum pump and a leakage valve (not shown) for changing the atmosphere of the load lock chamber 83 between the atmospheric atmosphere and the vacuum atmosphere.

As can be seen from the plane view of FIG. 7, the second transfer chamber 84 has, for example, a hexagonal shape, and its front two sides are connected to the load lock chambers 83 while the other four sides are connected to the processing modules 85a to 85d. Installed inside the second transfer chamber 84 is a second transfer device 87 for transferring the wafer W under the vacuum atmosphere between the load lock chambers 83 and the processing modules 85a to 85d, wherein the second transfer device 87 is configured to be rotatable and extensible/contractible. Further, the second transfer chamber 84 is connected to a vacuum pump (not shown) which maintains the inside of the second transfer chamber 84 under the vacuum atmosphere.

The processing modules 85a to 85d are connected to a vacuum pump (not shown), and are configured to perform various processes performed under the vacuum atmosphere, for example, an etching process using an etching gas, a film forming process such as CVD using a film forming gas, an ashing process using an ashing gas, and the like. Each processing module includes, for example, a processing vessel 91, a mounting table 92 for mounting the wafer W thereon, and a gas shower head 93 for supplying a processing gas into the processing vessel 91. Further, the mounting table 92 includes a heater 94 embedded therein, for heating the wafer W mounted on the mounting table 92 up to a certain temperature during the processing of the wafer W.

The processes performed by the processing modules 85a to 85d may be identical to or different from each other. Further, the transfer devices 10A and 87, the processing modules 85a to 85d, and so forth are connected to a control unit 8A for controlling the whole operation of the semiconductor manufacturing apparatus 8. The control unit 8A has the same configuration as that of the control unit 1A, and is configured to execute a program including processing steps for performing the operation of the semiconductor manufacturing apparatus 8 to be described later, wherein the program is stored in a storage unit 8B.

Now, a transfer path of the wafer W in the semiconductor manufacturing apparatus 8 will be explained. The wafer W stored in the carrier C on the carrier mounting table 81 is taken out of the carrier C by the transfer device 10A and is transferred into the first transfer chamber 82 and then into the alignment chamber 86. Further, the wafer W is heated up to a preset temperature, for example, about 40° C. by the transfer device 10A. The wafer W transferred into the alignment chamber 86 is aligned such that its notch N is oriented in a certain direction, and its temperature is kept regulated at the preset temperature by the pedestal 6. After the position alignment, the wafer W is transferred into either one of the left and right load lock chambers 83 by the transfer device 10A to be in a standby state therein.

Thereafter, if the inside of the load lock chamber 83 is turned into a vacuum atmosphere, the wafer W is taken out of the load lock chamber 83 by the transfer device 87 to be transferred into the second transfer chamber 84, and then is conveyed into one of the processing modules 85a to 85d. Then, the wafer W is mounted on the mounting table 92 of the one of the processing modules 85a to 85d, and heated up to a preset temperature and subjected to a certain process. Here, if the processing modules 85a to 85d perform a series of different processes, the wafer W is transferred between the second transfer chamber 84 and the respective processing modules 85 to 85d necessary for performing the series of processes.

After the necessary processes are completed in the processing modules 85a to 85d, the wafer W is transferred by the transfer device 87 into either one of the left and right load lock chambers 83 to be in a standby state therein. Then, if the inside of the load lock chamber 83 is turned into an atmospheric atmosphere and the temperature of the wafer W is cooled down to a preset temperature, the transfer device 10A carries the wafer W back to the carrier C, and during this transfer process, the wafer W is cooled to a certain temperature, for example, about 60° C.

In the semiconductor manufacturing apparatus 8 configured as described, since the wafer W is heated during its transfer by the transfer device 10A and during its position alignment in the alignment chamber 86, the particle adhesion to the wafer W can be prevented, so that reduction of yield can be suppressed. Moreover, when performing, for example, a CVD on the wafer W in the processing modules 85a to 85d, it is possible to form a film containing little impurity because organic matters adhered to the wafer W are removed during the temperature adjustment of the wafer W before the CVD is performed. Therefore, the reduction of yield can be further suppressed. Further, when cooling the wafer W, which is heated up to a high temperature in the processing modules 85a to 85d, in the load lock chamber 83, it is possible to take out the wafer W from the load lock chamber 83 even when the wafer W has a higher temperature in comparison with a case that the transfer device 10A does not have the temperature control function, because the temperature of the wafer W is controlled by the transfer device 10A before it reaches the carrier C. That is, the cooling time in the load lock chamber 83 can be shortened, resulting in improvement of throughput.

In addition, since the wafer W is heated by the transfer device 10A and the alignment chamber 86 before loaded into the processing modules 85a to 85d, it is possible to shorten the length of time for heating the wafer W till the wafer W reaches a processing temperature after it is mounted on the mounting table 92 of the processing modules 85a to 85d, so that the improvement of throughput can be achieved.

In the transfer device 10A, for example, it is desirable to discharge a lower temperature gas when transferring the wafer W from the load lock chamber 83 back into the carrier C, in comparison with the case of transferring the wafer W to the processing modules 85a to 85d via the load lock chamber 83, because waiting time of the wafer W in the load lock chamber 83 can be further shortened.

The substrate transfer device to which the present disclosure can be applied is not limited to the multi-joint arm described above, but the present disclosure can also be applied to a transfer device having a transfer arm which is installed at a revolvable transfer body and is movable back and forth. In such case, the transfer arm serves as a substrate supporting portion.

Further, as mentioned in the description of the background art, an example of the semiconductor manufacturing apparatus is a coating/developing apparatus employed in a photoresist process. The coating/developing apparatus is connected to an exposure apparatus for performing an exposure process, and includes a loading portion to which the carrier C is loaded; a coating module for coating a resist on a substrate; a developing module for supplying a developing solution to the resist having been subjected to the exposure process; and a transfer mechanism for conveying the substrate, which is transferred from the carrier C, from the coating module to the exposure apparatus, and conveying the substrate transferred from the exposure apparatus to the developing module and the carrier C in sequence. If the above-described orienter 5 is installed in the coating/developing apparatus and the substrate is transferred from the coating module to the orienter 5 and then to the exposure apparatus in order, temperature control and position adjustment for transferring the wafer W to the exposure apparatus can be performed at the same time, so that throughput can be improved in comparison with a case of performing the temperature control and the position adjustment individually. In such case, the orienter 5 is set to regulate the temperature of the wafer W at a level corresponding to the inside of the exposure apparatus, for example, about 23° C.

The above description of the present invention is provided for the purpose of illustration, and it would be understood by those skilled in the art that various changes and modifications may be made without changing technical conception and essential features of the present invention. Thus, it is clear that the above-described embodiments are illustrative in all aspects and do not limit the present invention.

The scope of the present invention is defined by the following claims rather than by the detailed description of the embodiment. It shall be understood that all modifications and embodiments conceived from the meaning and scope of the claims and their equivalents are included in the scope of the present invention.

What is claimed is:

1. A substrate supporting apparatus comprising:
a substrate supporting portion having a substrate supporting surface facing a rear surface of a substrate;
a plurality of protruding portions provided on the substrate supporting surface, for supporting the rear surface of the substrate and preventing the substrate from being slid on the substrate supporting surface by a friction force generated between the protruding portions and the substrate;
a gas discharge opening provided in the substrate supporting surface, for discharging a gas toward the rear surface of the substrate;
a gas flow path whose one end is connected to the gas discharge opening and the other end is connected to a gas supply source for supplying the gas to the gas discharge opening; and
a temperature control unit for controlling a temperature of the gas flowing through the gas flow path,
wherein the gas discharged to the rear surface of the substrate flows in a gap between the substrate supporting surface and the substrate, and by a Bernoulli effect causing a reduction of a pressure of the gap, the substrate is attracted to the substrate supporting portion, thereby supporting the substrate.

2. The substrate supporting apparatus of claim 1, further comprising:
a driving mechanism for allowing the substrate supporting portion to rotate about a vertical axis and to move forward and backward.

3. The substrate supporting apparatus of claim 2, wherein the driving mechanism constitutes a multi-joint arm together with the substrate supporting portion.

4. The substrate supporting apparatus of claim 2, wherein the gas flow path is formed inside the driving mechanism.

5. The substrate supporting apparatus of claim 1, wherein the substrate is a semiconductor wafer, and the substrate supporting portion is configured as a rotary stage for detecting a direction of the semiconductor wafer and adjusting the direction to be coincident with a preset direction.

6. A substrate supporting method comprising:
discharging a gas from a gas discharge opening provided in a substrate supporting surface toward a rear surface of a substrate placed on a plurality of protruding portions, in which the protruding portions are installed on the substrate supporting surface provided on a substrate supporting portion while facing the rear surface of the substrate, for supporting the rear surface of the substrate and preventing the substrate from being slid on the substrate supporting surface by a friction force generated between the protruding portions and the substrate;
controlling, by a temperature control unit, a temperature of the gas flowing through a gas flow path whose one end is connected to the gas discharge opening and the other end is connected to a gas supply source; and
supporting the substrate by the substrate supporting portion through attracting the substrate to the substrate supporting portion as a result of a Bernoulli effect which causes a reduction of a pressure of a gap between the substrate supporting surface and the substrate when the gas discharged to the rear surface of the substrate flows in the gap.

7. A semiconductor manufacturing apparatus comprising:
a first transfer chamber under an atmospheric atmosphere, including a mounting unit for mounting thereon a carrier for accommodating a substrate therein;
a load lock chamber including a mounting table for mounting thereon the substrate, for switching between an atmospheric atmosphere and a vacuum atmosphere;
a vacuum processing module connected to the first transfer chamber via the load lock chamber, for performing a process on the substrate under a vacuum atmosphere;
a first substrate transfer member for transferring the substrate between the carrier disposed in the first transfer chamber and the load lock chamber; and
a second substrate transfer member for transferring the substrate between the load lock chamber and the vacuum processing module,
wherein the first substrate transfer member is configured as the substrate supporting apparatus of claim 1.

8. The semiconductor manufacturing apparatus of claim 7, wherein an alignment chamber having a substrate position adjusting member for adjusting a position of the substrate is connected to the first transfer chamber, and
the substrate position adjusting member is configured as the substrate supporting apparatus of claim 5.

9. A storage medium for storing a program used in a substrate supporting apparatus, wherein the program includes steps for executing the substrate supporting method of claim 6.
